(19) United States
(12) Patent Application Publication
(10) Pub. No.: US 2014/0036458 A1
(43) Pub. Date: Feb. 6, 2014

(54) ELECTRONIC APPARATUS

(71) Applicant: KABUSHIKI KAISHA TOSHIBA, Tokyo (JP)

(72) Inventors: Yuki Sato, Ome-shi (JP); Yuji Nakajima, Nishitama-gun (JP)

(73) Assignee: KABUSHIKI KAISHA TOSHIBA, Tokyo (JP)

(21) Appl. No.: 14/015,678

(22) Filed: Aug. 30, 2013

Related U.S. Application Data
(63) Continuation of application No. PCT/JP2013/057947, filed on Mar. 13, 2013.

(30) Foreign Application Priority Data
Jul. 31, 2012 (JP) 2012-169482

(51) Int. Cl. H05K 7/02

(52) U.S. Cl. CPC H05K 7/02
USPC 361/749

(57) ABSTRACT

According to one embodiment, an electronic apparatus includes a housing, a sheet display, a circuit board, and a touch sensor. The housing includes a wall opposite an opening. The sheet display includes a first surface and a second surface. The first surface includes a display screen configured to expose through the opening. The circuit board is configured to connect to the sheet display via a flexible wiring board. The circuit board is between the sheet display and the wall, and configured to control the sheet display. The touch sensor includes a portion between the sheet display and the circuit board. The touch sensor faces the second surface of the sheet display, and is configured to detect an operation on the display screen.

### CROSS REFERENCE TO RELATED APPLICATIONS

This application is a Continuation Application of PCT Application No. PCT/JP2013/057947, filed Mar. 13, 2013 and based upon and claiming the benefit of priority from Japanese Patent Application No. 2012-169482, filed Jul. 31, 2012, the entire contents of all of which are incorporated herein by reference.

### FIELD

Embodiments described herein relate generally to electronic apparatuses.

### BACKGROUND

Some electronic apparatuses include a display and a touch sensor which overlaps a display screen of the display.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view of an electronic apparatus according to a first embodiment;

FIG. 2 is an exemplary perspective view of a front mask illustrated in FIG. 1;

FIG. 3 is an exemplary cross-sectional view of the electronic apparatus illustrated in FIG. 1;

FIG. 4 is an exemplary cross-sectional view of an electronic apparatus according to a second embodiment;

FIG. 5 is an exemplary cross-sectional view of an electronic apparatus according to a third embodiment;

FIG. 6 is an exemplary cross-sectional view of an electronic apparatus according to a fourth embodiment;

FIG. 7 is an exemplary cross-sectional view of an electronic apparatus according to a fifth embodiment;

FIG. 8 is an exemplary cross-sectional view of an electronic apparatus according to a sixth embodiment; and

FIG. 9 is an exemplary cross-sectional view of an electronic apparatus according to a seventh embodiment.

### DETAILED DESCRIPTION

Various embodiments will be described hereinafter with reference to the accompanying drawings.

In general, according to one embodiment, an electronic apparatus comprises a housing, a sheet display, a circuit board, and a touch sensor. The housing comprises an opening and a wall opposite the opening. The sheet display comprises a first surface and a second surface opposite the first surface. The first surface comprises a display screen configured to expose through the opening. The circuit board is configured to connect to the sheet display via a flexible wiring board. The circuit board is between the sheet display and the wall, and configured to control the sheet display. The touch sensor comprises a portion between the sheet display and the circuit board. The touch sensor faces the second surface of the sheet display, and is configured to detect an operation on the display screen.

Hereinafter, embodiments will be described with reference to the drawings. In this specification, some components are expressed by two or more terms. Those terms are just examples. Those components may be further expressed by another or other terms. And the other components which are not expressed by two or more terms may be expressed by another or other terms.

### First Embodiment

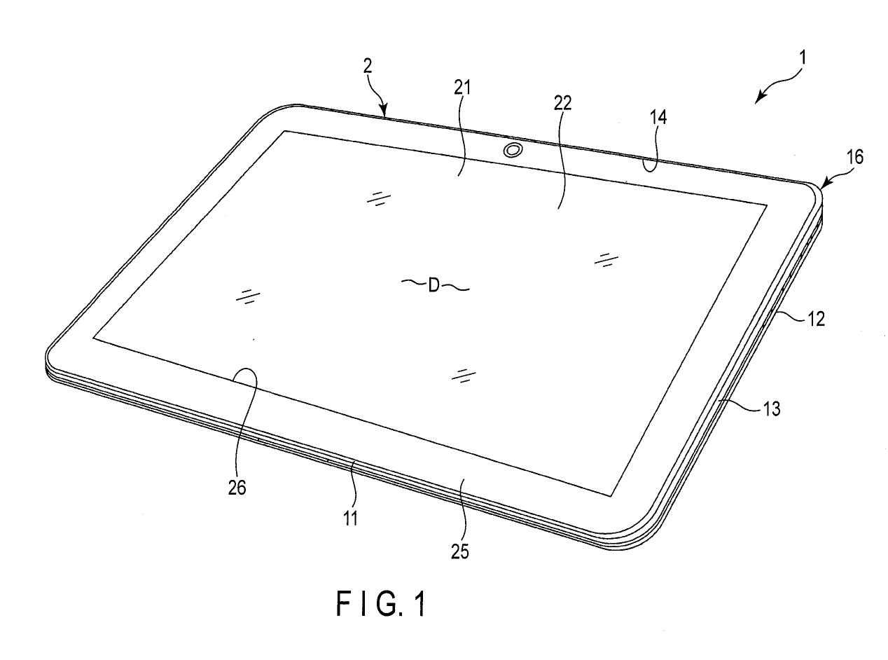

First, an electronic apparatus 1 according to a first embodiment will be described with reference to FIGS. 1 to 3. As illustrated in FIG. 1, the electronic apparatus 1 according to this embodiment is a tablet portable computer (i.e., a tablet terminal or a slate portable computer). The electronic apparatus to which this embodiment can be applied is not limited to the above-mentioned example. The structure according to this embodiment can be widely applied to, for example, various electronic apparatuses, such as notebook portable computers, televisions, mobile phones (including smart phones), and game machines.

As illustrated in FIG. 1, the electronic apparatus 1 includes a housing 2 with a flat box shape. The housing 2 includes a first wall 11 (e.g., an upper wall or a front wall), a second wall 12 (e.g., a bottom wall, a lower wall, or a rear wall), and a third wall 13 (e.g., a circumferential wall or a side wall).

The first wall 11 faces the user. As illustrated in FIGS. 1 to 3, a relatively large first opening 14 is provided in the first wall 11. Therefore, in this embodiment, the first wall 11 has a thin frame shape surrounding the first opening 14.

The second wall 12 is opposite to the first wall 11 (i.e., the first opening 14). The second wall 12 faces a desk surface (i.e., a mounting surface, an external surface, or an external mounting surface), for example, when the electronic apparatus 1 is placed on the desk. The third wall 13 extends in a direction intersecting (e.g., substantially perpendicular to) the first wall 11 and the second wall 12 and connects the edge of the first wall 11 and the edge of the second wall 12. The third wall 13 extends between the first wall 11 and the second wall 12 (i.e., between the first opening 14 and the second wall 12).

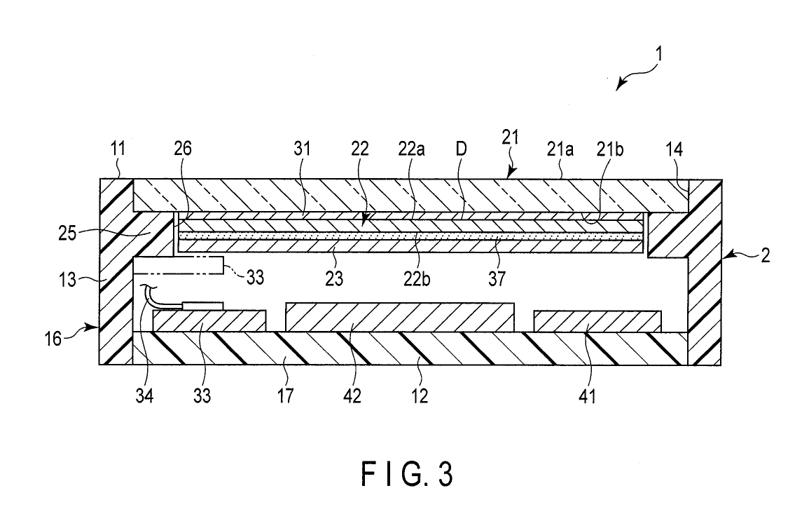

As illustrated in FIG. 3, the housing 2 includes a front mask 16 (i.e., a front cover, a mask, a first cover, or a first member) and a rear cover 17 (i.e., a base, a cover, a second cover, or a second member). Each of the front mask 16 and the rear cover 17 is an example of a housing member, an outer member, or an outer surface member which is exposed to the outside of the electronic apparatus 1.

The front mask 16 includes the first wall 11 and the third wall 13 and has a bowl shape with the bottom open. The rear cover 17 includes the second wall 12 and has a plate shape. In this embodiment, the rear cover 17 is fitted to the inside of the third wall 13 of the front mask 16 to form the housing 2.

As illustrated in FIG. 3, the electronic apparatus 1 includes a protective panel 21, a sheet display 22, and a touch sensor 23. The protective panel 21 (i.e., a protective portion, a protective sheet, a panel, or a translucent portion) is made of, for example, glass (e.g., chemically strengthened glass) or plastic and is light-permeable (i.e., light-transmitting).

The protective panel 21 has, for example, a plate shape and includes a first surface 21a and a second surface 21b opposite to the first surface 21a. The first surface 21a of the protective panel 21 is exposed to the outside and forms a portion of the outer surface (i.e., outermost surface) of the electronic apparatus 1. The second surface 21b of the protective panel 21 faces the inside of the housing 2.

The first wall 11 of the housing 2 has a frame shape surrounding the protective panel 21. In other words, the protective panel 21 is accommodated in the first opening 14 and is disposed in the first opening 14. The first surface 21a of the protective panel 21 is substantially flush with, for example, the outer surface of the first wall 11 and is continuous with the outer surface of the first wall 11.

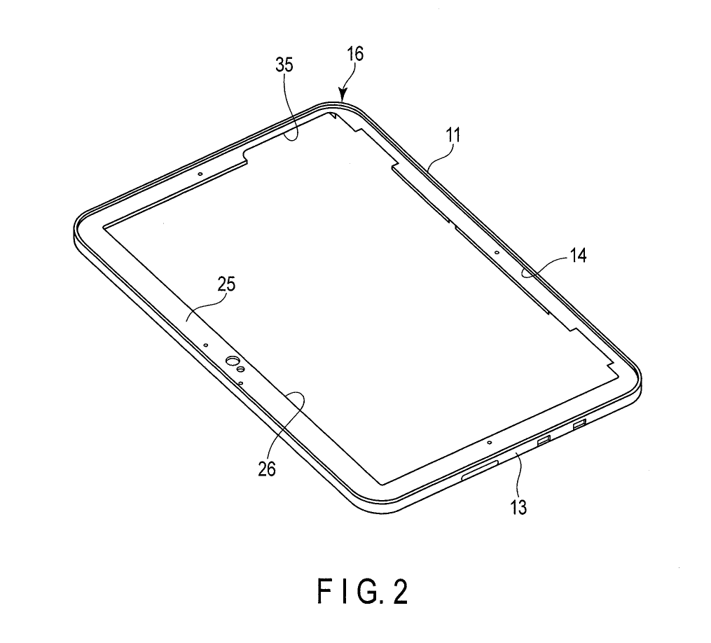

As illustrated in FIGS. 2 and 3, the housing 2 includes a supporting portion 25 (i.e., a protrusion, an extending portion, a holder, an attachment portion, a rib, an engaging portion, an annular portion, or a frame portion) which supports the protective panel 21. The supporting portion 25 is a portion of the front mask 16 and is integrated with the front mask 16. The supporting portion 25 protrudes from the inner surface of the third wall 13 to the inside of the housing 2.

The supporting portion 25 protrudes in a direction substantially parallel to the second wall 12 of the housing 2 (i.e., in a direction substantially perpendicular to the thickness direction of the housing 2). The supporting portion 25 has a frame shape (i.e., annular shape) along the inner surface of the third wall 13. The supporting portion 25 is disposed close to the first wall 11. For example, the supporting portion 25 is recessed from the outer surface of the first wall 11 by a depth corresponding to the thickness of the protective panel 21.

As illustrated in FIG. 3, the second surface 21b of the protective panel 21 is placed on the supporting portion 25. For example, an adhesive is provided between the protective panel 21 and the supporting portion 25. In this way, the protective panel 21 is fixed to the supporting portion 25. The supporting portion 25 supports the edge of the protective panel 21 from the inner of the housing 2.

As illustrated in FIG. 2, the supporting portion 25 continuously protrudes from the entire inner surface (i.e., inner circumferential surface) of the third wall 13. In this way, the supporting portion 25 defines a second opening 26 of the housing 2 on the rear side of the protective panel 21. The second opening 26 is smaller than the first opening 14 and communicates with the inside of the housing. From another point of view, one opening including the first opening 14 and the second opening 26 is provided in the housing 2.

The sheet display 22 (i.e., a display unit, a display device, a display module, a display panel, a panel, or a display sheet) is a sheet-shaped display and has, for example, flexibility (i.e., bendability). An example of the sheet display 22 is a plastic organic EL display (OELD; Organic Electro-Luminescent Display). For example, the thickness of the sheet display 22 is less than that of the protective panel 21 or the second wall 12 of the housing 2. For example, the thickness of the sheet display 22 is equal to or less than 1 mm.

The thickness or material of the sheet display 22 according to this embodiment is not particularly limited. Various kinds of sheet displays 22 may be used as long as the touch sensor 23 provided on the rear side of the sheet display 22 can detect an operation on the surface of the sheet display 22, which will be described below.

The sheet display 22 includes a first surface 22a and a second surface 22b. The first surface 22a includes a display screen D on which an image or a video is displayed. The first surface 22a faces the second surface 21b of the protective panel 21 and is covered with the protective panel 21. The display screen D is exposed to the outside of the housing 2 through the first opening 14 of the housing 2. The second surface 22b is opposite to the first surface 22a and faces the inside of the housing 2.

The term “exposed to the outside” includes a case in which the display screen D is directly exposed to the outside and a case in which the display screen D is exposed to the outside through a light-permeable member (e.g., the protective panel 21). That is, the term “exposed to the outside” means visible from the outside.

As illustrated in FIG. 3, the sheet display 22 is smaller than the protective panel 21 and is disposed in the second opening 26. That is, at least a portion of the sheet display 22 is disposed inside the frame-shaped supporting portion 25. In this embodiment, the entire sheet display 22 is disposed in the second opening 26. Alternatively, a portion of or the entire sheet display 22 may protrude toward the outside of the second opening 26.

As illustrated in FIG. 3, a light-permeable adhesive 31 (i.e., a light-permeable adhesive layer, an optical translucent adhesive, or an optical clear adhesive (hereinafter, referred to as an OCA 31)) is provided between the protective panel 21 and the sheet display 22. The protective panel 21 and the sheet display 22 are bonded to each other by the OCA 31.

As illustrated in FIG. 3, a circuit board 33 (i.e., a control board, a driving board, or a sub-board) driving the sheet display 22 is provided in the housing 2. The circuit board 33 is connected to the sheet display 22 via, for example, a flexible wiring board 34. The circuit board 33 according to this embodiment is also connected to the touch sensor 23 via, for example, the flexible wiring board 34. That is, the circuit board 33 controls the touch sensor 23 and receives the detection result from the touch sensor 23.

As illustrated in FIG. 2, a through portion 35 (i.e., a communication portion or an insertion portion) through which the flexible wiring board 34 passes is provided in the supporting portion 25 of the housing 2. An example of the through portion 35 is a cutout which is provided in the inner circumference edge of the supporting portion 25. Instead of the cutout, a through hole may be provided in the supporting portion 25.

As illustrated in FIG. 3, the circuit board 33 is separated from the sheet display 22 and the touch sensor 23 and is disposed between the sheet display 22 and the second wall 12 of the housing 2. In this embodiment, the circuit board 33 is attached to the inner surface of the second wall 12 of the housing 2. The circuit board 33 may be attached to the supporting portion 25, as represented by a two-dot chain line in FIG. 3. In addition, the circuit board 33 may be attached to the third wall 13 or other positions. The circuit board 33 may be incorporated into a circuit board 41 (e.g., main board), which will be described below.

As illustrated in FIG. 3, the touch sensor 23 (i.e., a touch panel, a sensor unit, a detection unit, an operation unit, an input unit, or an input receiving unit) has, for example, a sheet shape. For example, the size of the touch sensor 23 is substantially equal to that of the sheet display 22.

In this embodiment, the touch sensor 23 is disposed closer to the inside of the housing 2 than the sheet display 22. That is, the touch sensor 23 is provided on the rear side (i.e., back side) of the sheet display 22. The touch sensor 23 faces the second surface 22b of the sheet display 22.

For example, the sheet display 22 according to this embodiment is sufficiently thin. The touch sensor 23 can detect an operation of the user on the display screen D of the sheet display 22, with the sheet display 22 interposed therebetween. The touch sensor 23 is, for example, a capacitive detection device, but it may be a pressure-sensitive detection device. The touch sensor 23 according to this embodiment may not be light-permeable.

When an operation for writing an image to lines (e.g., scanning lines) of the sheet display 22 interferes with the detection operation of the touch sensor, the detection accuracy (i.e., sensitivity) of the touch sensor 23 is likely to be reduced. For example, a blank state (i.e., no signal is transmitted for a predetermined period of time) is given in a driving frequency for writing images to the sheet display 22 and the touch sensor 23 performs a detection operation in the blank state. This control makes it possible to ensure sufficiently high detection accuracy of the touch sensor 23.

As illustrated in FIG. 3, an adhesive 37 (e.g., adhesive layer) is provided between the second surface 22b of the sheet display 22 and the touch sensor 23. The second surface 22b of the sheet display 22 is bonded to the touch sensor 23 by the adhesive 37. The adhesive 37 does not need to be a light-permeable adhesive, but is, for example, a general adhesive.

As illustrated in FIG. 3, a portion of the touch sensor 23 is disposed between the sheet display 22 and the circuit board 33. In this embodiment, the touch sensor 23 is disposed in the second opening 26. That is, at least a portion of the touch sensor 23 is disposed inside the frame-shaped supporting portion 25. In this embodiment, the entire touch sensor 23 is disposed in the second opening 26. Alternatively, a portion of or the entire touch sensor 23 may protrude toward the outside of the second opening 26.

As illustrated in FIG. 3, the housing 2 includes a circuit board 41 (e.g., main board) and a battery 42. The circuit board 41 controls the overall operation of the electronic apparatus 1, for example. The circuit board 41 and the battery 42 are attached to, for example, the inner surface of the second wall 12, but the attachment position is not limited thereto.

According to the above-mentioned structure, it is possible to reduce the costs of the electronic apparatus 1 and improve the brightness of the screen and operability.

For comparison, an electronic apparatus including a display and a touch sensor which overlaps the display screen of the display is considered. For example, the display is thick and includes a metal plate or a metal frame. In this case, when the touch sensor is mounted on the rear surface of the display, it is difficult to detect an operation on the display screen. Therefore, the touch sensor is mounted on the front surface of the display.

The electronic apparatus further includes, for example, a protective panel on the front surface side of the touch sensor. That is, the touch sensor is disposed between the protective panel and the display. OCAs are provided between the protective panel and the touch sensor and between the touch sensor and the display.

In a process of manufacturing the electronic apparatus, first, the protective panel and the touch sensor are bonded to each other by a first OCA. At that time, there is the risk of air bubbles being generated between the protective panel and the touch sensor. Then, the touch sensor and the display are bonded to each other by a second OCA. At that time, there is the risk of air bubbles being generated between the touch sensor and the display. That is, in the process of manufacturing the electronic apparatus, the risk of air bubbles being generated on the front surface side of the display screen is doubled.

In the electronic apparatus, there are the boundary (e.g., first boundary) between the protective panel and the first OCA, the boundary (e.g., second boundary) between the first OCA and the touch sensor, the boundary (e.g., third boundary) between the touch sensor and the second OCA, and the boundary (e.g., fourth boundary) between the second OCA and the display on the front side of the display screen.

Light emitted from the display screen is reflected from the interface between members with different refractive indexes. Therefore, a layer which transmits light emitted from the display screen is as small as possible in order to improve the brightness of the screen. In the electronic apparatus, there are four interfaces on the front side of the display screen.

In contrast, the electronic apparatus 1 according to this embodiment includes the housing 2, the sheet display 22, and the touch sensor 23. The opening 14 is provided in the housing 2. The sheet display 22 includes the first surface 22a including the display screen D which is exposed from the opening 14 and the second surface 22b opposite to the first surface 22a. The touch sensor 23 faces the second surface 22b of the sheet display 22 and is configured to detect an operation for the display screen D.

That is, in this embodiment, the touch sensor 23 is provided on the rear side (i.e., back side) of the sheet display 22. For example, the sheet display 22 is sufficiently thin and has an insulating property. That is, the sheet display 22 does not substantially include a metal portion which makes it difficult for the touch sensor 23, such as a metal plate or a metal frame, to detect an operation. Therefore, the touch sensor 23 mounted on the rear side of the sheet display 22 can detect an operation for the display screen D.

In an example of the process of manufacturing the electronic apparatus 1, first, for example, the second surface 22b of the sheet display 22 and the touch sensor 23 are bonded to each other by a general adhesive. The adhesion is performed on the rear surface side of the display screen D. Therefore, even when air bubbles are generated, they are not viewed from the outside. That is, there is no risk of air bubbles.

Then, the protective panel 21 and the sheet display 22 are bonded to each other by the OCA. At that time, there is the risk of air bubbles being generated between the protective panel 21 and the sheet display 22. However, in the process of manufacturing the electronic apparatus 1 according to this embodiment, air bubbles are likely to be generated on the front surface side of the display screen D only one time.

That is, the risk of air bubbles is reduced by half, as compared to the electronic apparatus according to the comparative example. When the risk of air bubbles affecting product quality is reduced, product yield is improved and product costs are reduced.

In the electronic apparatus 1 according to this embodiment, there are only two interfaces, that is, the boundary (e.g., first boundary) between the protective panel 21 and the OCA 31 and the boundary (e.g., second boundary) between the OCA 31 and the sheet display 22 on the front side of the display screen D. That is, while there are four interfaces on the front surface side of the display screen D in the electronic apparatus according to the comparative example, there are two interfaces in the electronic apparatus 1 according to this embodiment. Therefore, loss due to reflection from the interface between layers is reduced. As a result, the brightness of the screen is improved and thus the visibility of the screen is improved.

In this embodiment, the number of layers provided on the front side of the display screen D is reduced and the display screen D is disposed at a position close to the outermost surface (i.e., a position closer to the user), as compared to the electronic apparatus according to the comparative example. Therefore, it is possible to reduce the discomfort of the user due to the positional deviation of a touch operation. As a result, the operability of the electronic apparatus 1 is improved.

In this embodiment, the electronic apparatus 1 further includes the circuit board 33 which is connected to the sheet display 22 via the flexible wiring board 34. The circuit board 33 is disposed between the sheet display 22 and the second wall 12 and drives the sheet display 22. A portion of the touch sensor 23 is disposed between the sheet display 22 and the circuit board 33. According to this structure, for example, the second wall 12 of the housing 2 or the supporting portion 25 is used to mount the circuit board 33 and it is possible to reduce the size or thickness of the electronic apparatus 1.

In this embodiment, the electronic apparatus 1 further includes the protective panel 21 which faces the first surface 22a of the sheet display 22. The housing 2 includes the third wall 13 extending between the opening 14 and the second wall 12. The third wall 13 includes the frame-shaped supporting portion 25 which protrudes from the inner surface of the third wall 13 and supports the edge of the protective panel 21 from the inner side of the housing 2. At least a portion of the sheet display 22 is disposed inside the frame-shaped supporting portion 25. According to this structure, it is possible to further reduce the thickness of the electronic apparatus 1.

In this embodiment, at least a portion of the touch sensor 23 is disposed inside the frame-shaped supporting portion 25. According to this structure, it is possible to further reduce the thickness of the electronic apparatus 1.

In this embodiment, the second surface 22b of the sheet display 22 and the touch sensor 23 are bonded to each other by the adhesive 37. According to this structure, an attachment portion to which the touch sensor 23 is attached is not needed. Therefore, it is possible to further reduce the size or thickness of the electronic apparatus 1.

### Second Embodiment

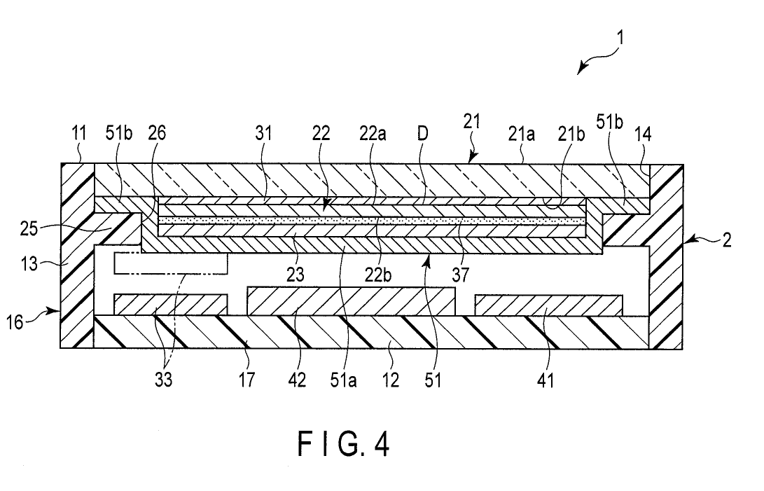

Next, an electronic apparatus 1 according to a second embodiment will be described with reference to FIG. 4. In the second embodiment, components having the similar or same functions as those in the first embodiment are denoted by the same reference numerals and the description thereof will not be repeated. Structures other than the following structures are the same as those in the first embodiment.

As illustrated in FIG. 4, the electronic apparatus 1 according to this embodiment includes a middle plate 51 (i.e., a middle frame, a reinforcing plate, a metal portion, a holding portion, a plate, or a reinforcing portion) made of a metal material. The middle plate 51 is an example of a “supporting portion.” The middle plate 51 includes a first portion 51a (e.g., a supporting portion in a narrow sense) and a second portion 51b (e.g., an attachment portion or a fixing portion).

The first portion 51a has, for example, a plate shape which is substantially parallel to a touch sensor 23 and is disposed closer to the inside of a housing 2 than the touch sensor 23. That is, the first portion 51a is disposed between the touch sensor 23 and a second wall 12 of the housing 2. The first portion 51a faces the rear surface (e.g., lower surface) of the touch sensor 23 and supports the touch sensor 23 and a sheet display 22 from the inner side of the housing 2.

The first portion 51a supports at least a central portion of the touch sensor 23 and at least a central portion of the sheet display 22 from the inner side of the housing 2. In this embodiment, the first portion 51a covers, for example, the entire touch sensor 23 and the entire sheet display 22 from the lower side and supports the entire touch sensor 23 and the entire sheet display 22. The middle plate 51 receives, for example, the operation of the user pressing a display screen D and prevents the touch sensor 23 and the sheet display 22 from being bent.

The first portion 51a is an example of a shield portion which shields electromagnetic waves (e.g., unnecessary radiation). In this embodiment, the entire middle plate 51 is made of a metal material and is connected to the ground of the electronic apparatus 1. The entire middle plate 51 functions as a shield portion.

For example, the first portion 51a, which is a shield portion, is disposed between the touch sensor 23 and a circuit board 33 and shields at least some of the electromagnetic waves emitted from the circuit board 33 toward the touch sensor 23. In addition, the first portion 51a is disposed between the touch sensor 23 and a circuit board 41 and shields at least some of the electromagnetic waves emitted from the circuit board 41 toward the touch sensor 23.

In this embodiment, the circuit board 33 is attached to, for example, the inner surface of the second wall 12 of the housing 2. As represented by a two-dot chain line in FIG. 4, the circuit board 33 is attached to the middle plate 51. In this case, the circuit board 33 is thermally connected to the middle plate 51 and heat is dissipated by the middle plate 51.

The second portion 51b is fixed to the housing 2. In this embodiment, for example, the second portion 51b rises from the first portion 51a, the end of the second portion 51b is bent toward the outside, and the second portion 51b is disposed between a protective panel 21 and a supporting portion 25. In this embodiment, the second portion 51b is fixed to the supporting portion 25. The structure of the second portion 51b is not limited thereto, but the second portion 51b may be fixed to the housing 2 at other positions.

As illustrated in FIG. 4, in this embodiment, at least a portion of the middle plate 51 is disposed in a second opening 26. That is, at least a portion of the middle plate 51 is disposed inside the frame-shaped supporting portion 25. In this embodiment, a portion of the middle plate 51 protrudes toward the outside of the second opening 26. Alternatively, the entire middle plate 51 may be disposed in the second opening 26.

According to this structure, similarly to the first embodiment, it is possible to reduce the costs of the electronic apparatus 1 and improve the brightness of the screen and operability. According to this embodiment, it is possible to improve operability, the detection accuracy of the touch sensor 23, and the radiation performance of the electronic apparatus 1.

The sheet display 22 according to this embodiment is relatively thin such that the touch sensor 23 provided on the rear side of the sheet display 22 can detect an operation. Therefore, the sheet display 22 is soft and is likely to be bent. In addition, the touch sensor 23 is relatively thin and soft and is likely to be bent. Therefore, the sheet display 22 and the touch sensor 23 are likely to be bent toward the inside of the housing 2 by pressure caused by the touch operation of the user.

However, the electronic apparatus 1 according to this embodiment includes the middle plate 51 which supports at least the central portion of the touch sensor 23 from the inner side of the housing 2. In this way, the sheet display 22 and the touch sensor 23 are less likely to be bent toward the inside of the housing 2. Therefore, the operation of the user is likely to be stabilized, which makes it possible to further improve the operability of the electronic apparatus 1.

The circuit board 33 or other electronic components (e.g., the circuit board 41) provided in the housing 2 emit electromagnetic waves. When the touch sensor 23 is mounted on the rear surface (e.g., lower surface) of the sheet display 22, the distance between the touch sensor 23 and the circuit board 33 or the electronic components is reduced. Therefore, the detection accuracy of the touch sensor 23 is likely to be reduced by the electromagnetic waves.

However, in this embodiment, the middle plate 51 includes the shield portion which is made of a metal material and is disposed between the touch sensor 23 and the circuit board 33. Therefore, the electromagnetic waves emitted from the circuit board 33 are shielded by the middle plate 51 and are less likely to affect the detection of the touch sensor 23. In addition, the middle plate 51 shields electromagnetic waves emitted from other electronic components which are provided in the housing 2 and prevents the electromagnetic waves from affecting the detection of the touch sensor 23. Therefore, even when the touch sensor 23 is mounted on the rear surface (e.g., lower surface) of the sheet display 22, it is possible to improve the detection accuracy of the touch sensor 23.

The circuit board 33 or an electronic component (e.g., the circuit board 41) generates heat when it is driven. When the heat is locally transmitted to the sheet display 22, a defect, such as the local distortion of the display screen D, occurs.

However, in this embodiment, the middle plate 51 made of a metal material is provided between the circuit board 33 or an electronic component and the touch sensor 23. Therefore, heat generated from the circuit board 33 or the electronic component is dissipated by the middle plate 51 and is less likely to be locally transmitted to the sheet display 22. Therefore, it is possible to prevent a defect, such as the distortion of the display screen D. In addition, heat transmitted to the middle plate 51 is dissipated by the middle plate 51. Therefore, it is possible to improve the radiation performance of the electronic apparatus 1.

In this embodiment, at least a portion of the middle plate 51 is disposed inside the frame-shaped supporting portion 25. According to this structure, it is possible to further reduce the thickness of the electronic apparatus 1.

### Third Embodiment

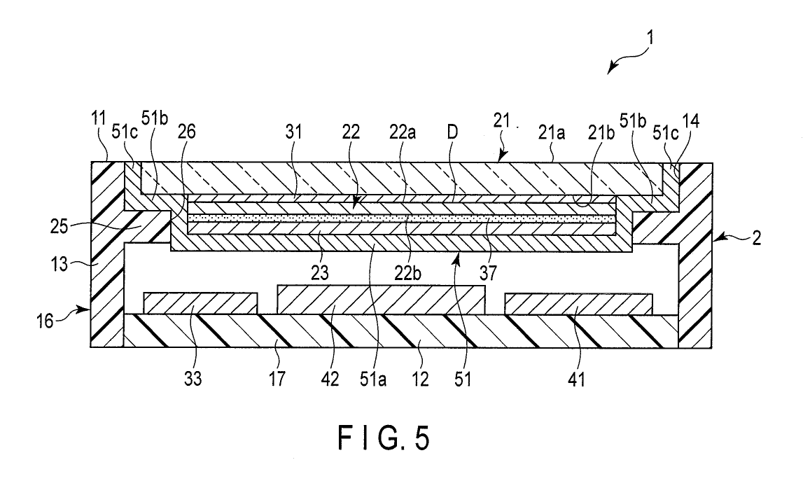

Next, an electronic apparatus 1 according to a third embodiment will be described with reference to FIG. 5. In the third embodiment, components having the similar or same functions as those in the first and second embodiments are denoted by the same reference numerals and the description thereof will not be repeated. Structures other than the following structures are the same as those in the second embodiment.

As illustrated in FIG. 5, in this embodiment, a middle plate 51 includes a third portion 51c (e.g., a protruding portion, a conductive portion, or a static electricity receiving portion). For example, the third portion 51c is disposed between the inner circumferential surface of a first opening 14 and a sheet display 22 and is exposed to the outside of the housing 2. The leading end of the third portion 51c is substantially flush with, for example, a first surface 21a of the protective panel 21 and forms a portion of the outermost surface of the electronic apparatus 1. The third portion 51c is configured to receive static electricity charged in the finger of the user who operates the display screen D.

According to this structure, similarly to the second embodiment, it is possible to reduce the costs of the electronic apparatus 1 and improve the brightness of the screen, operability, the detection accuracy of a touch sensor 23, and the radiation performance of the electronic apparatus 1.

According to this embodiment, the third portion 51c of the middle plate 51 functions as a portion which discharges static electricity. The third portion 51c can prevent the influence of static electricity on the sheet display 22 or the touch sensor 23 and protect the sheet display 22 or the touch sensor 23. This contributes to improving the reliability or lifespan of the electronic apparatus 1.

### Fourth Embodiment

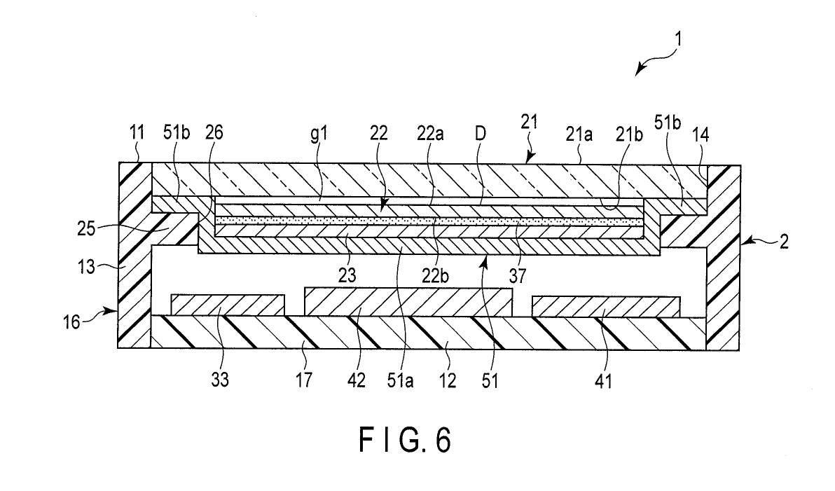

Next, an electronic apparatus 1 according to a fourth embodiment will be described with reference to FIG. 6. In the fourth embodiment, components having the similar or same functions as those in the first and second embodiments are denoted by the same reference numerals and the description thereof will not be repeated. Structures other than the following structures are the same as those in the second embodiment.

As illustrated in FIG. 6, in this embodiment, an OCA 31 is provided between a protective panel 21 and a sheet display 22. In this embodiment, the protective panel 21 is not bonded to the sheet display 22. A gap g1 (i.e., air layer) is formed between the protective panel 21 and the sheet display 22.

According to this structure, similarly to the second embodiment, it is possible to reduce the costs of the electronic apparatus 1 and improve the brightness of the screen, operability, the detection accuracy of a touch sensor 23, and the radiation performance of the electronic apparatus 1.

According to this embodiment, since there is no adhesive layer on the front side of a display screen D, it is possible to completely remove the risk of air bubbles being generated on the front side of the display screen D. Therefore, it is possible to further improve product yield. In addition, when the protective panel 21 is not bonded to the sheet display 22, it is easy to disassemble the electronic apparatus and maintainability is improved.

### Fifth Embodiment

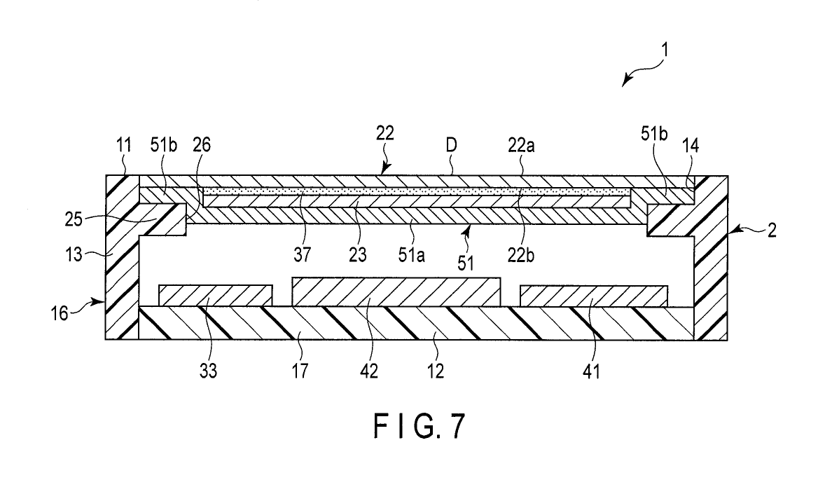

Next, an electronic apparatus 1 according to a fifth embodiment will be described with reference to FIG. 7. In the fifth embodiment, components having the similar or same functions as those in the first and second embodiments are denoted by the same reference numerals and the description thereof will not be repeated. Structures other than the following structures are the same as those in the second embodiment.

As illustrated in FIG. 7, in this embodiment, a protective panel 21 is not provided. That is, a sheet display 22 is provided on the outermost surface of the electronic apparatus 1.

According to this structure, similarly to the second embodiment, it is possible to reduce the costs of the electronic apparatus 1 and improve the brightness of the screen, operability, the detection accuracy of a touch sensor 23, and the radiation performance of the electronic apparatus 1.

According to this embodiment, since there is no layer which causes interface reflection on the front side of a display screen D, the brightness of the screen is further improved and the visibility of the screen is improved. According to this embodiment, since the distance between the display screen D and the user is further reduced, it is possible to further reduce the discomfort of the user due to the positional deviation of a touch operation, which makes it possible to further improve the operability of the electronic apparatus 1.

### Sixth Embodiment

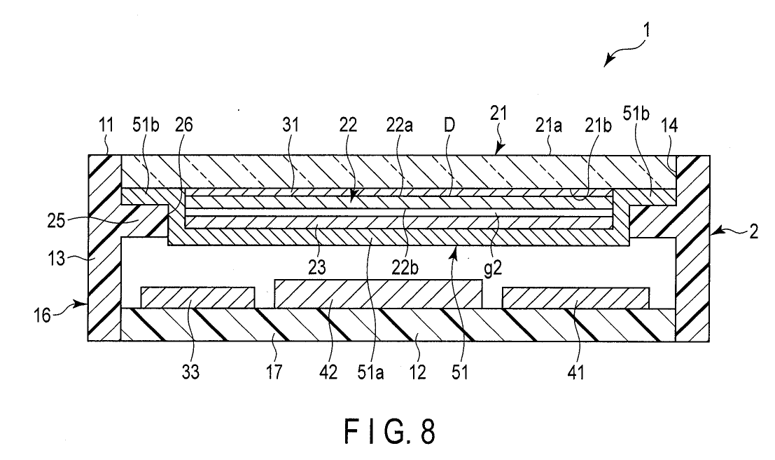

Next, an electronic apparatus 1 according to a sixth embodiment will be described with reference to FIG. 8. In the sixth embodiment, components having the similar or same functions as those in the first and second embodiments are denoted by the same reference numerals and the description thereof will not be repeated. Structures other than the following structures are the same as those in the second embodiment.

As illustrated in FIG. 8, in this embodiment, an adhesive 37 is not provided between a sheet display 22 and a touch sensor 23. In this embodiment, the sheet display 22 is not bonded to the touch sensor 23. A gap g2 (i.e., air layer) is formed between the sheet display 22 and the touch sensor 23.

According to this structure, similarly to the second embodiment, it is possible to reduce the costs of the electronic apparatus 1 and improve the brightness of the screen, operability, the detection accuracy of the touch sensor 23, and the radiation performance of the electronic apparatus 1.

According to this embodiment, since an operation for bonding the sheet display 22 and the touch sensor 23 is not performed, it is possible to improve assemblability. In addition, when the sheet display 22 is not bonded to the touch sensor 23, it is easy to disassemble the electronic apparatus and maintainability is improved.

In a modification of this embodiment, as the touch sensor 23, a force sensor that detects a variation in the clearance between the sheet display 22 and the touch sensor 23 may be used.

Specifically, in the modification, a protective panel 21 is made of, for example, plastic such that it can be bent. When the user presses a display screen D, the sheet display 22 is bent toward the inside of the housing 2 and the gap g2 between the sheet display 22 and the touch sensor 23 is changed. The touch sensor 23 detects a variation in capacitance based on the change in the gap g2 between the sheet display 22 and the touch sensor 23. In this way, the touch sensor 23 can detect an operation of pressing the display screen D in addition to an operation of touching the display screen D. According to the electronic apparatus 1, it is possible to further improve the operability (e.g., the diversity of operations) of the electronic apparatus 1.

### Seventh Embodiment

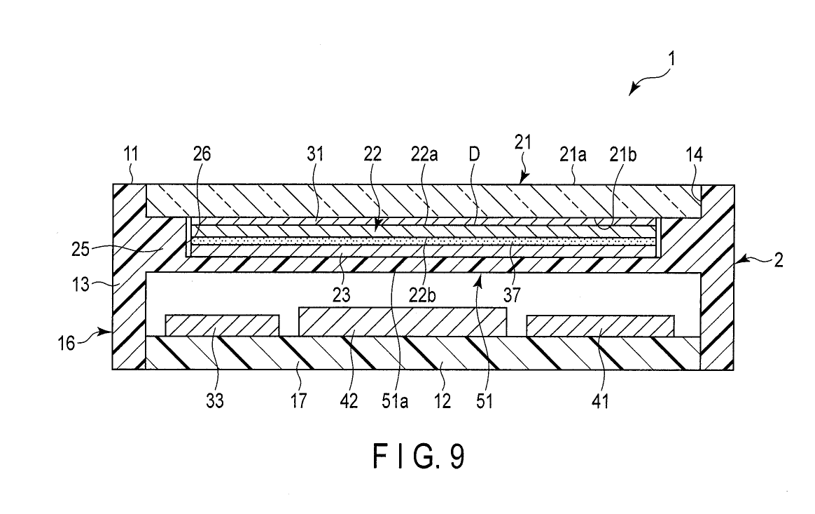

Next, an electronic apparatus 1 according to a seventh embodiment will be described with reference to FIG. 9. In the seventh embodiment, components having the similar or same functions as those in the first and second embodiments are denoted by the same reference numerals and the description thereof will not be repeated. Structures other than the following structures are the same as those in the second embodiment.

As illustrated in FIG. 9, in this embodiment, instead of the middle plate 51, a supporting portion 25 which supports a sheet display 22 and a touch sensor 23 is provided in a housing 2. The supporting portion 25 supports at least a central portion of the touch sensor 23 and at least a central portion of the sheet display 22 from the inner side of the housing 2.

According to this structure, similarly to the second embodiment, it is possible to reduce the costs of the electronic apparatus 1 and improve the brightness of the screen and operability.

According to the above-described first to seventh embodiments, it is possible to reduce the costs of the electronic apparatus 1 and improve the brightness of the screen and operability.

The embodiments are not limited to the above-described embodiments, but the components according to the above-described embodiments may be changed without departing from the scope and spirit of the invention. In addition, a plurality of components according to the above-described embodiments may be appropriately combined with each other to form various structures. For example, some of the components according to the above-described embodiments may be removed. Components according to different embodiments may be appropriately combined with each other.

For example, the sheet display 22 and the touch sensor 23 may be attached to the housing 2, the middle plate 51, or other members.

Next, an electronic apparatus will be additionally described.

According to an embodiment, an electronic apparatus comprises a housing, a sheet display, and a touch sensor. The housing comprises an opening. The sheet display comprises a first surface and a second surface opposite to the first surface. The first surface comprises a display screen configured to expose through the opening. The touch sensor faces the second surface of the sheet display and is configured to detect an operation on the display screen.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing comprising an opening and a wall opposite the opening;
a sheet display comprising a first surface and a second surface opposite the first surface, the first surface comprising a display screen configured to be exposed through the opening;
a circuit board configured to connect to the sheet display via a flexible wiring board, the circuit board between the sheet display and the wall, and configured to drive the sheet display; and
a touch sensor comprising a portion between the sheet display and the circuit board, the touch sensor facing the second surface of the sheet display, and configured to detect an operation on the display screen.

2. The electronic apparatus of claim 1, further comprising:
a first supporting portion comprising a portion between the touch sensor and the wall, the first supporting portion configured to support at least a central portion of the touch sensor from an inner side of the housing.

3. The electronic apparatus of claim 2,
wherein the first supporting portion is a metal plate comprising a shield portion between the touch sensor and the circuit board, the plate attached to the housing.

4. The electronic apparatus of claim 2, further comprising:
a protective panel facing the first surface of the sheet display,
wherein the housing comprises a side wall extending between the opening and the wall,
the side wall comprises a frame-shaped second supporting portion protruding from an inner surface of the side wall and configured to support an edge of the protective panel from the inner side of the housing, and
at least a portion of the sheet display is inside the frame-shaped second supporting portion.

5. The electronic apparatus of claim 4,
wherein at least a portion of the touch sensor is inside the frame-shape second supporting portion.

6. The electronic apparatus of claim 4,
wherein at least a part of the first supporting portion is inside the frame-shaped second supporting portion.

7. The electronic apparatus of claim 1,
wherein the second surface of the sheet display and the touch sensor are bonded to each other by adhesive.

8. The electronic apparatus of claim 1,
wherein a gap is between the second surface of the sheet display and the touch sensor.

9. The electronic apparatus of claim 8,
wherein the touch sensor is configured to detect a variation in capacitance based on a change in the gap between the sheet display and the touch sensor when the display screen is pressed.

10. The electronic apparatus of claim 3,
wherein the plate comprises a portion extending between an inner circumferential surface of the opening and an outer circumferential surface of the sheet display and configured to expose the portion of the plate configured to receive static electricity outside of the housing.
